(19) United States
(12) Patent Application Publication
(10) Pub. No.: US 2026/0136793 A1
(43) Pub. Date: May 14, 2026

(54) DISPLAY DEVICE

(71) Applicant: Sharp Kabushiki Kaisha, Sakai City (JP)

(72) Inventors: Hideki KITAGAWA, Sakai City (JP); Yoshihito HARA, Sakai City (JP); Masaki MAEDA, Sakai City (JP); Jun NISHIMURA, Sakai City (JP); Yoshiharu HIRATA, Sakai City (JP); Kengo HARA, Sakai City (JP)

(21) Appl. No.: 19/384,055

(22) Filed: Nov. 10, 2025

(30) Foreign Application Priority Data
Nov. 13, 2024 (JP) 2024-198193

(51) Int. Cl. H10K 59/131; H10K 59/121

(52) U.S. Cl. CPC H10K 59/1315; H10K 59/1213

(57) ABSTRACT

A display device includes a base substrate, a thin film transistor layer provided on the base substrate and including a low-resistance conductive layer including a copper film, the low-resistance conductive layer being disposed corresponding to each subpixel of a plurality of subpixels constituting a display region, and a light-emitting element layer provided on the thin film transistor layer and including a plurality of first electrodes, a plurality of light-emitting function layers, and a common second electrode sequentially layered corresponding to the plurality of subpixels, in which each of the first electrodes includes a silver film and is electrically connected to the low-resistance conductive layer, and the low-resistance conductive layer is covered with a first metal layer having etching resistance to an etching solution for the silver film.

### CROSS-REFERENCE TO RELATED APPLICATIONS

This application claims the benefit of priority to Japanese Patent Application Number 2024-198193 filed on Nov. 13, 2024. The entire contents of the above-identified application are hereby incorporated by reference.

### BACKGROUND

### Technical Field

The disclosure relates to a display device.

In recent years, as a display device replacing a liquid crystal display device, a self-luminous organic electroluminescence (hereinafter also referred to as “EL”) display device using an organic EL element has attracted attention. The organic EL display device includes, for example, a base substrate, a TFT layer provided on the base substrate and on which a thin film transistor (hereinafter, also referred to as a “TFT”) layer is disposed, an organic EL element layer provided on the TFT layer and on which a plurality of organic EL elements are disposed corresponding to a plurality of subpixels constituting a display region, and a sealing film provided on the organic EL element layer. Here, the organic EL element includes, for example, a first electrode provided on the TFT layer, an organic EL layer provided on the first electrode, and a second electrode provided on the organic EL layer.

For example, JP 2014-513313 T discloses a display device including a light emitting diode constituted by sequentially layering a transparent electrode, a light-emitting layer, and a reflective electrode.

Further, WO 2023/105569 discloses an organic EL display device in which a first metal layer including a copper film is provided in a TFT layer, and a pixel electrode corresponding to the first electrode is formed of a second metal layer including a silver film.

### SUMMARY

In the organic EL display device in which, as in WO 2023/105569, for example, a copper film having a lower electrical resistance than an aluminum film is used for a conductive layer such as a wiring line or an electrode of the TFT layer and a silver film is used for a first electrode of an organic EL element layer, when the silver film is patterned by wet etching when forming the first electrode, a low-resistance conductive layer using the copper film of the TFT electrically connected to the first electrode may be corroded by an etching solution for the silver film.

The disclosure has been made in view of such circumstances, and an object thereof is to suppress corrosion of the low-resistance conductive layer using the copper film of the TFT layer electrically connected to the first electrode using the silver film.

In order to achieve the object, a display device according to the disclosure includes a base substrate, a thin film transistor layer provided on the base substrate and including a low-resistance conductive layer including a copper film, the low-resistance conductive layer being disposed corresponding to each subpixel of a plurality of subpixels constituting a display region, and a light-emitting element layer provided on the thin film transistor layer and including a plurality of first electrodes, a plurality of light-emitting function layers, and a common second electrode sequentially layered corresponding to the plurality of subpixels, in which each of the first electrodes includes a silver film and is electrically connected to the low-resistance conductive layer, and the low-resistance conductive layer is covered with a first metal layer having etching resistance to an etching solution for the silver film.

According to the disclosure, it is possible to suppress corrosion of the low-resistance conductive layer using the copper film of the TFT layer electrically connected to the first electrode using the silver film.

### BRIEF DESCRIPTION OF DRAWINGS

The disclosure will be described with reference to the accompanying drawings, wherein like numbers reference like elements.

FIG. 1 is a plan view of an organic EL display device according to a first embodiment of the disclosure, schematically illustrating a configuration of the device.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is a cross-sectional view of a terminal portion of the organic EL display device according to the first embodiment of the disclosure.

FIG. 5 is an equivalent circuit diagram of a TFT layer included in the organic EL display device according to the first embodiment of the disclosure.

FIG. 6 is a cross-sectional view of an organic EL layer included in the organic EL display device according to the first embodiment of the disclosure.

FIG. 7 is a cross-sectional view of a terminal portion of the organic EL display device according to a second embodiment of the disclosure.

FIG. 8 is a cross-sectional view of a terminal portion of the organic EL display device according to a third embodiment of the disclosure.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

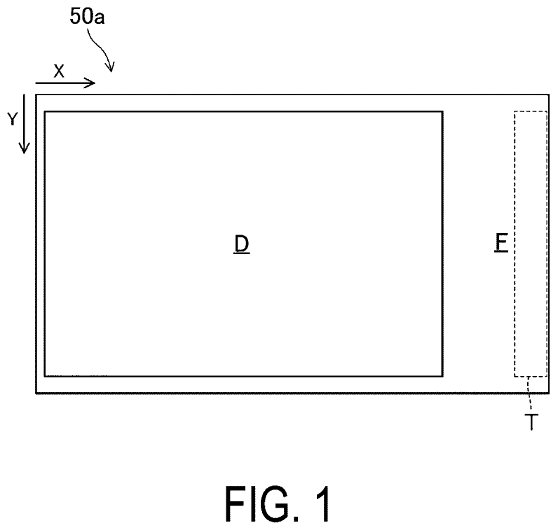

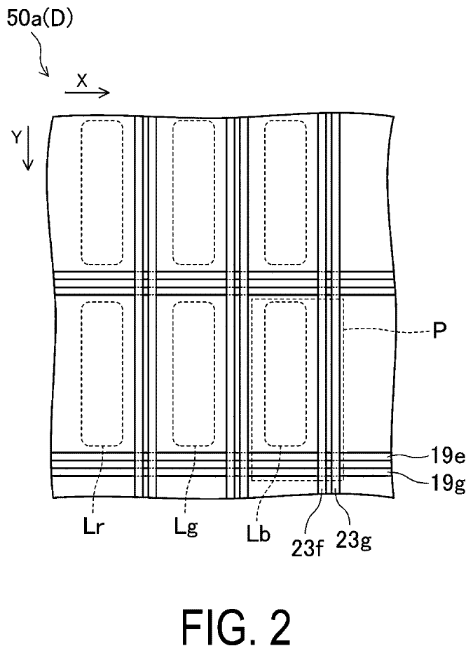

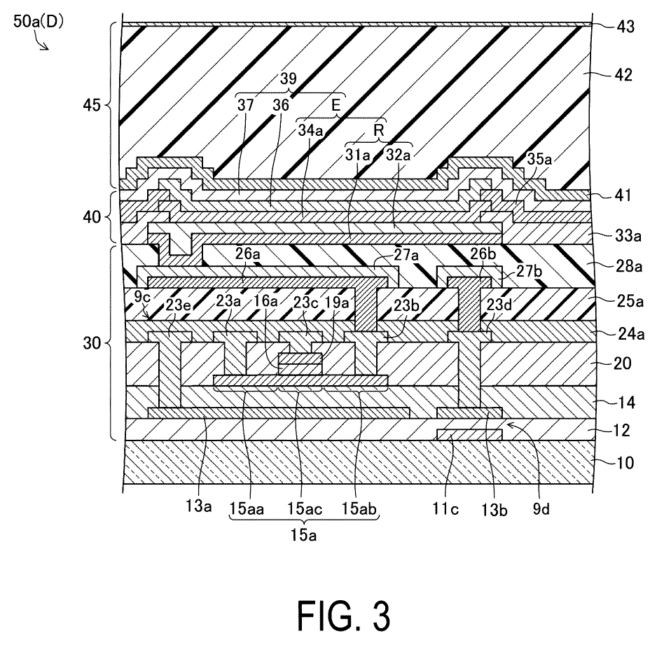

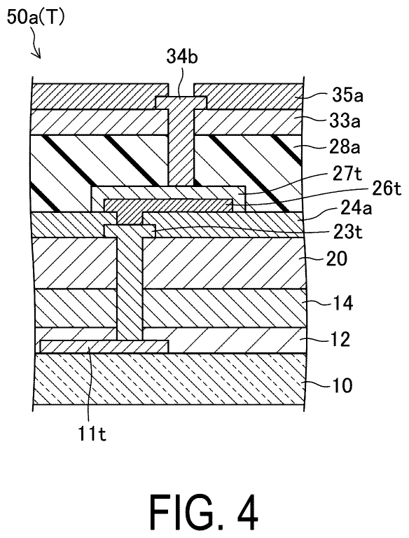

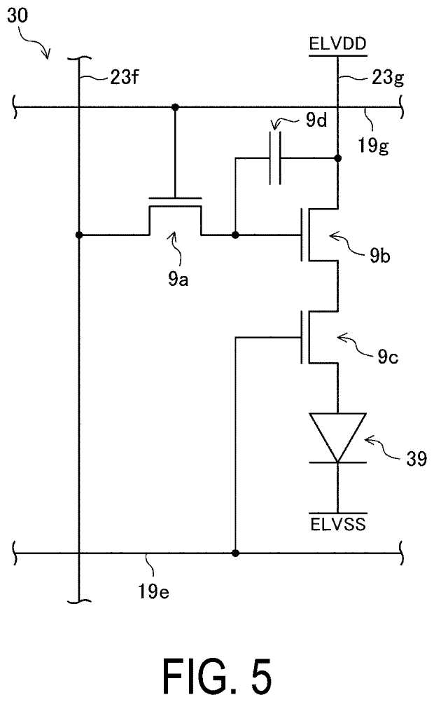

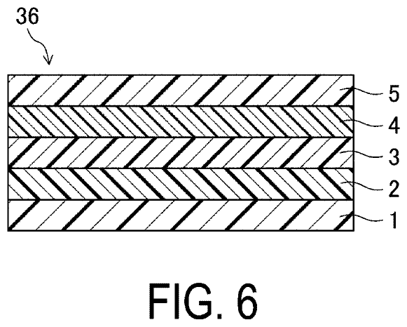

FIG. 1 to FIG. 6 illustrate a first embodiment of a display device according to the disclosure. Here, FIG. 1 is a plan view illustrating a schematic configuration of an organic EL display device 50a according to the present embodiment. FIG. 2 and FIG. 3 are a plan view and a cross-sectional view, respectively, of a display region D in the organic EL display device 50a. FIG. 4 is a cross-sectional view of a terminal portion T of the organic EL display device 50a. FIG. 5 is an equivalent circuit diagram of a TFT layer 30, which is a component of the organic EL display device 50a. FIG. 6 is a cross-sectional view illustrating an organic EL layer 36 included in the organic EL display device 50a.

As illustrated in FIG. 1, the organic EL display device 50a includes, for example, the display region D that is provided in a rectangular shape and in which an image is displayed, and a frame region F provided in a frame-like shape around the display region D. Note that, in the present embodiment, the display region D having the rectangular shape is exemplified, but the rectangular shape includes a substantially rectangular shape such as a shape whose sides are arc-shaped, a shape whose corners are arc-shaped, and a shape in which a part of a side has a notch.

As illustrated in FIG. 2, a plurality of subpixels P are arrayed in a matrix shape in the display region D. In the display region D, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another, as illustrated in FIG. 2. Note that one pixel is configured by, for example, three adjacent subpixels P including the red light-emitting region Lr, the green light-emitting region Lg, and the blue light-emitting region Lb in the display region D.

The terminal portion T is provided extending in one direction (Y direction in FIG. 1) at an end portion of the frame region F on a positive side in an X direction in FIG. 1. In the organic EL display device 50a, display wiring lines such as gate lines 19g, light emission control lines 19 e, source lines 23f, and power source lines 23g, which are provided in the display region D and will be described later, are drawn toward the terminal portion T.

As illustrated in FIG. 3, the organic EL display device 50a includes a glass substrate 10 provided as a base substrate, the TFT layer 30 provided on the glass substrate 10, an organic EL element layer 40 provided as a light-emitting element layer on the TFT layer 30, and a sealing film 45 provided on the organic EL element layer 40.

The glass substrate 10 is constituted to have, for example, a thickness from about 0.1 mm to about 0.5 mm.

As illustrated in FIG. 3, the TFT layer 30 includes a plurality of first TFTs 9a (see FIG. 5) provided on the glass substrate 10, a plurality of second TFTs 9b (see FIG. 5), a plurality of third TFTs 9c, and a plurality of capacitors 9d, and a protective insulating film 24a, a first flattening film 25a, and a second flattening film 28a sequentially provided on each of the first TFTs 9a, each of the second TFTs 9b, each of the third TFTs 9c, and each of the capacitors 9d.

As illustrated in FIG. 3, in the TFT layer 30, a first metal film that becomes a first capacitance electrode 11c and the like described later, a base insulating film (first inorganic insulating film) 12, a second metal film that becomes a first gate electrode 13a and the like described later, a first gate insulating film (second inorganic insulating film) 14, a semiconductor film that becomes a semiconductor layer 15a and the like described later, a second gate insulating film (third inorganic insulating film) 16a, a third metal film that becomes a second gate electrode 19a and the like described later, an interlayer insulating film (fourth inorganic insulating film) 20, a fourth metal film that becomes a source electrode 23a and the like described later, a protective insulating film (fifth inorganic insulating film) 24a, a first flattening film (first organic insulating film) 25a, a fifth metal film that becomes a relay electrode 26a and the like described later, a sixth metal film that becomes a first metal layer 27a and the like described later, and a second flattening film (second organic insulating film) 28a are sequentially layered on the glass substrate 10. Here, the base insulating film 12, the first gate insulating film 14, the second gate insulating film 16a, the interlayer insulating film 20, and the protective insulating film 24a are each constituted of, for example, a single-layer film or a layered film of an inorganic insulating film such as a silicon nitride film, a silicon oxide film, or a silicon oxynitride film. Note that a semiconductor layer 15a side of the first gate insulating film 14 and a semiconductor layer 15a side of the second gate insulating film 16a are each constituted of, for example, a silicon oxide film. The fifth metal film includes a copper film having a low electrical resistance. The interlayer insulating film 20 may be constituted, for example, by sequentially layering a first interlayer insulating film and a second interlayer insulating film.

As illustrated in FIG. 2, in the TFT layer 30, a plurality of the gate lines 19g are provided to extend parallel to each other in the X direction in the drawing. As illustrated in FIG. 2, in the TFT layer 30, a plurality of the light emission control lines 19e are provided to extend parallel to each other in the X direction in the drawing. Note that, as illustrated in FIG. 2, each of the light emission control lines 19e is provided adjacent to a corresponding one of the gate lines 19g. In addition, as illustrated in FIG. 2, in the TFT layer 30, a plurality of source lines 23f are provided to extend parallel to each other in the Y direction in the figure. In addition, as illustrated in FIG. 2, in the TFT layer 30, a plurality of power source lines 23g are provided to extend parallel to each other in the Y direction in the figure. Note that, as illustrated in FIG. 2, each of the power source lines 23g is provided adjacent to a respective one of the source lines 23f. In addition, in the TFT layer 30, as illustrated in FIG. 5, each subpixel P includes the first TFT 9a, the second TFT 9b, the third TFT 9c, and the capacitor 9d. Here, each of the gate lines 19g and each of the light emission control lines 19e are formed of the third metal film and each of the source lines 23f and each of the power source lines 23g are formed of the fourth metal film.

As illustrated in FIG. 5, the first TFT 9a is electrically connected to the corresponding gate line 19g, the source line 23f, and the second TFT 9b in each subpixel P. Note that the first TFT 9a has substantially the same structure as the third TFT 9c to be described later.

As illustrated in FIG. 5, the second TFT 9b is electrically connected to the corresponding first TFT 9a, the power source line 23g, and the third TFT 9 c in each subpixel P. Note that the second TFT 9b has substantially the same structure as the third TFT 9c to be described later.

As illustrated in FIG. 5, the third TFT 9c is electrically connected to the corresponding second TFT 9b, and a first electrode E constituting an organic EL element 39 described later and the light emission control line 19e, in each subpixel P. Further, as illustrated in FIG. 3, the third TFT 9c includes the semiconductor layer 15a, the first gate electrode 13a provided on the glass substrate 10 side of the semiconductor layer 15a with the first gate insulating film 14 interposed therebetween, the second gate electrode 19a provided opposite to the glass substrate 10 side of the semiconductor layer 15a with the second gate insulating film 16a interposed therebetween, and the source electrode 23a and the drain electrode 23b provided so as to be separated from each other on the interlayer insulating film 20.

The semiconductor layer 15a is formed of a semiconductor film made of, for example, an In—Ga—Zn—O based oxide semiconductor, and includes, as illustrated in FIG. 3, a source region 15aa and a drain region 15ab defined so as to be separated from each other, and a channel region 15ac defined between the source region 15aa and the drain region 15ab. Here, the In—Ga—Zn—O based semiconductor is ternary oxide of indium (In), gallium (Ga), and zinc (Zn), and a ratio (a composition ratio) of each of In, Ga, and Zn is not particularly limited to a specific value. The In—Ga—Zn—O based semiconductor may be an amorphous semiconductor or may be a crystalline semiconductor. Note that as a crystalline In—Ga—Zn—O based semiconductor, a crystalline In—Ga—Zn—O based semiconductor in which the c-axis is oriented substantially perpendicular to the layer surface is preferable. In place of the In—Ga—Zn—O based semiconductor, another oxide semiconductor may be included. Examples of the other oxide semiconductor may include an In—Sn—Zn—O based semiconductor (for example, In₂O₃—SnO₂—ZnO; InSnZnO). Here, the In—Sn—Zn—O based semiconductor is ternary oxide of indium (In), tin (Sn), and zinc (Zn). Alternatively, examples of the other oxide semiconductor may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (MgₓZn₁₋ₓO), and cadmium zinc oxide (CdₓZn₁₋ₓO). Note that, as the Zn—O based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a semiconductor in a polycrystalline state, a semiconductor in a microcrystalline state in which the non-crystalline state and the polycrystalline state are mixed, or a semiconductor to which no impurity element is added can be used.

As illustrated in FIG. 3, the first gate electrode 13a is provided so as to overlap the semiconductor layer 15a, and is constituted to control characteristics such as an S-value (rising coefficient in a subthreshold region) of the third TFT 9c. As illustrated in FIG. 3, the first gate electrode 13a is electrically connected to a wiring line layer 23e through a contact hole formed in the first gate insulating film 14 and the interlayer insulating film 20. Similarly to the source line 23f and the like, the wiring line layer 23e, the source electrode 23a, the drain electrode 23b, and a wiring line layer 23c, a first wiring line layer 23d, and a second terminal layer 23t, which will be described later, are formed of the fourth metal film.

As illustrated in FIG. 3, the second gate electrode 19a is provided so as to overlap the channel region 15ac of the semiconductor layer 15a, and is configured to control conduction between the source region 15aa and the drain region 15ab of the semiconductor layer 15a. Here, as illustrated in FIG. 3, the second gate electrode 19a is electrically connected to the wiring line layer 23c through a contact hole formed in the interlayer insulating film 20. Similarly to the gate line 19g and the like, the second gate electrode 19a is formed of the third metal film.

As illustrated in FIG. 3, the source electrode 23a and the drain electrode 23b are electrically connected to the source region 15aa and the drain region 15ab, respectively, of the semiconductor layer 15a, through the respective contact holes formed in the interlayer insulating film 20. As illustrated in FIG. 3, the drain electrode 23b is electrically connected to the relay electrode 26a formed of the fifth metal film through a contact hole formed in the protective insulating film 24a and the first flattening film 25a. The relay electrode 26a is provided as a low-resistance conductive layer, and is covered with the first metal layer 27a formed of the sixth metal film as illustrated in FIG. 3. The sixth metal film is formed of a titanium film, a titanium alloy film, or the like having tolerability to an etching solution (for example, a mixed solution of phosphoric acid, nitric acid, and acetic acid) for the silver film constituting the first electrode E.

Note that, in the present embodiment, the first TFT 9a, the second TFT 9b, and the third TFT 9c of a double gate type are exemplified, but the first TFT 9a, the second TFT 9b, and the third TFT 9c may be of a top gate type or a bottom gate type. In the present embodiment, the first TFT 9a, the second TFT 9b, and the third TFT 9c including the semiconductor layer 15a made of the oxide semiconductor are exemplified, but the semiconductor layer 15a may be made of, for example, polysilicon such as low temperature polysilicon (LTPS). Furthermore, the TFT layer 30 may have a hybrid structure in which a TFT including a semiconductor layer formed of polysilicon and a TFT including a semiconductor layer formed of an oxide semiconductor are provided.

As illustrated in FIG. 5, the capacitor 9d is electrically connected to the corresponding first TFT 9a and power source line 23g in each subpixel P. As illustrated in FIG. 3, the capacitor 9d includes the first capacitance electrode 11c formed of the first metal film, a second capacitance electrode 13b formed of the second metal film, and the base insulating film 12 provided between the first capacitance electrode 11c and the second capacitance electrode 13b. Here, as illustrated in FIG. 3, the second capacitance electrode 13b is electrically connected to the first wiring line layer 23d formed of the fourth metal film through a contact hole formed in the first gate insulating film 14 and the interlayer insulating film 20. As illustrated in FIG. 3, the first wiring line layer 23d is electrically connected to the second wiring line layer 26b formed of the fifth metal film through a contact hole formed in the protective insulating film 24a and the first flattening film 25a. Further, as illustrated in FIG. 3, the second wiring line layer 26b is covered with a second metal layer 27b formed of the sixth metal film. The first wiring line layer 23d is electrically connected to the power source line 23g.

The first flattening film 25a and the second flattening film 28a have a flat surface in the display region D, and are formed of, for example, an organic resin material such as a polyimide resin or an acrylic resin, or a polysiloxane-based spin on glass (SOG) material.

As illustrated in FIG. 3, the organic EL element layer 40 includes a plurality of the first electrodes E, a plurality of the organic EL layers 36, and a common second electrode 37, which are sequentially layered corresponding to the plurality of subpixels P. Here, in each subpixel P, the first electrode E, the organic EL layer 36, and the second electrode 37 constitute the organic EL element 39, as illustrated in FIG. 3, and in the organic EL element layer 40, a plurality of the organic EL elements 39 provided corresponding to the plurality of subpixels P are disposed in a matrix shape.

A plurality of the first electrodes E are provided in a matrix shape on the second flattening film 28a so as to correspond to the plurality of subpixels P. As illustrated in FIG. 3, the first electrode E is electrically connected to the drain electrode 23b of each third TFT 9c through a contact hole formed in the second flattening film 28a, the first metal layer 27a, the relay electrode 26a, and a contact hole formed in the first flattening film 25a and the protective insulating film 24a. As illustrated in FIG. 3, the first electrode E includes a reflective electrode R provided on the second flattening film 28a and a transparent electrode 34a provided on the reflective electrode R.

As illustrated in FIG. 3, the reflective electrode R includes a transparent conductive layer 31a provided on the second flattening film 28a, and a metal layer 32a provided on the transparent conductive layer 31a. Here, as illustrated in FIG. 3, a circumferential end portion of the reflective electrode R is covered with a first edge cover 33a provided in a lattice pattern in the entire display region D. Note that the first edge cover 33a is constituted of an inorganic insulating film that is a single-layer film or a layered film of silicon nitride, silicon oxide, silicon oxynitride, or the like, for example.

The transparent conductive layer 31a is formed of, for example, a transparent conductive film such as Indium-Tin-Oxide (hereinafter, also referred to as “ITO”) film and has optical transparency.

The metal layer 32a is formed of, for example, a metal film such as a silver film or a silver alloy film, and has light reflectivity.

The transparent electrode 34a has a function to inject a hole (positive hole) into the organic EL layer 36. Additionally, the transparent electrode 34a is preferably made of a material having a high work function to improve hole injection efficiency into the organic EL layer 36. Here, the transparent electrode 34a is formed of, for example, a transparent conductive film such as ITO film or the like, and has optical transparency. As illustrated in FIG. 3, a circumferential end portion of the transparent electrode 34a is covered with a second edge cover 35a provided in a lattice pattern in the entire display region D. Note that the second edge cover 35a is constituted of an inorganic insulating film that is a single-layer film or a layered film of silicon nitride, silicon oxide, silicon oxynitride, or the like, for example.

The organic EL layer 36 is provided as a light-emitting function layer and includes a hole injection layer 1, a hole transport layer 2, a light-emitting layer 3, an electron transport layer 4, and an electron injection layer 5 that are sequentially layered on the transparent electrode 34a, as illustrated in FIG. 6. In the present embodiment, the configuration in which each of the plurality of light-emitting function layers is the organic EL layer 36 has been exemplified, but at least one of the plurality of light-emitting function layers may be the organic EL layer 36.

The hole injection layer 1 is also referred to as an anode electrode buffer layer, and has a function to reduce an energy level difference between the transparent electrode 34a and the organic EL layer 36 and to improve hole injection efficiency from the transparent electrode 34a to the organic EL layer 36. Here, examples of materials constituting the hole injection layer 1 include polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function to improve efficiency of hole transport from the transparent electrode 34a to the organic EL layer 36. Here, examples of materials constituting the hole transport layer 2 include triphenylamine derivatives, porphyrin derivatives, aromatic tertiary amine compounds, styrylamine derivatives, polyvinyl carbazole, poly-p-phenylenevinylene, polysilane, polyarylalkane derivatives, pyrazoline derivatives, pyrazolone derivatives, phenylenediamine derivatives, arylamine derivatives, amine-substituted chalcone derivatives, fluorenone derivatives, hydrazone derivatives, hydrogenated amorphous silicon, hydrogenated amorphous silicon carbide, zinc sulfide, and zinc selenide.

The light-emitting layer 3 is a region where, when a voltage is applied by the transparent electrode 34a and the second electrode 37, a hole and an electron are injected from the transparent electrode 34a and the second electrode 37, respectively, and the hole and the electron are recombined. Here, the light-emitting layer 3 is made of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include imidazole derivatives, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 has a function to reduce an energy level difference between the second electrode 37 and the organic EL layer 36 and to improve efficiency of electron injection from the second electrode 37 into the organic EL layer 36, and this function can lower a drive voltage of the organic EL element 39. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

The second electrode 37 is provided on the plurality of organic EL layers 36 so as to be common to the plurality of subpixels P, that is, the second electrode 37 is provided to cover each of organic EL layers 36 and the second edge cover 35a, as illustrated in FIG. 3. Further, the second electrode 37 has a function to inject electrons into the organic EL layer 36. Further, the second electrode 37 is preferably made of a material having a low work function to improve efficiency of electron injection into the organic EL layer 36. Here, the second electrode 37 is formed of, for example, a transparent conductive film made of an ITO film, an IZO film, or the like, and an extremely thin metal film such as an MgAg film or the like, and has optical transparency.

As illustrated in FIG. 3, the sealing film 45 is provided so as to cover the second electrode 37, includes a first inorganic sealing film 41, an organic sealing film 42, and a second inorganic sealing film 43 that are sequentially layered on the second electrode 37, and has a function to protect the organic EL layer 36 of the organic EL element 39 from moisture, oxygen, and the like.

The first inorganic sealing film 41 and the second inorganic sealing film 43 are constituted of, for example, an inorganic insulating film such as a silicon nitride film, a silicon oxide film, or a silicon oxynitride film.

The organic sealing film 42 is made of, for example, an organic resin material such as an acrylic resin, an epoxy resin, a silicone resin, a polyurea resin, a parylene resin, a polyimide resin, a polyamide resin, or the like.

The organic EL display device 50a includes a plurality of first terminal layers 26t (see FIG. 4) provided along a direction (Y direction in FIG. 1), in which the terminal portion T extends, in the terminal portion T in the frame region F and formed of the fifth metal film. Here, as illustrated in FIG. 4, in the terminal portion T, the first flattening film 25a is not provided and the second flattening film 28a is provided.

As illustrated in FIG. 4, the first terminal layer 26t is covered with a third metal layer 27t formed of the sixth metal film. As illustrated in FIG. 4, the first terminal layer 26t is electrically connected to the second terminal layer 23t formed of the fourth metal film through a contact hole formed in the protective insulating film 24a. Here, the second terminal layer 23t is electrically connected to a third terminal layer 11t formed of the first metal film through a contact hole formed in the interlayer insulating film 20, the first gate insulating film 14, and the base insulating film 12. As illustrated in FIG. 4, the third metal layer 27t is electrically connected to the fourth terminal layer 34b formed of the same material and in the same layer as the transparent electrode 34a, through a contact hole formed in the second flattening film 28a and the first edge cover 33a. Note that as illustrated in FIG. 4, a circumferential end portion of the fourth terminal layer 34b is covered with the second edge cover 35a. The third terminal layer 11t is electrically connected to the display wiring lines such as the gate line 19g, the light emission control line 19e, the source line 23f, the power source line 23g, and the like.

In the organic EL display device 50a having the configuration described above, in each subpixel P, by inputting a gate signal to the first TFT 9a through the gate line 19g, the first TFT 9a is turned on. When a predetermined voltage corresponding to a source signal is written to a gate electrode of the second TFT 9b and the capacitor 9d through the source line 23f, and a light emission control signal is input to the third TFT 9c through the light emission control line 19e, the third TFT 9c is turned on. Then, by supplying a current corresponding to the gate voltage of the second TFT 9b from the power source line 23g to the organic EL layer 36 of the organic EL element 39, the light-emitting layer 3 of the organic EL layer 36 emits light to display an image. Note that, in the organic EL display device 50a, even when the first TFT 9a becomes an off state, the gate voltage of the second TFT 9b is held by the capacitor 9d, and thus light emission by the light-emitting layer 3 is maintained in each subpixel P until a gate signal of the next frame is input.

Next, a method of manufacturing the organic EL display device 50a according to the present embodiment will be described. Note that the manufacturing method for the organic EL display device 50a according to the present embodiment includes a TFT layer forming step, an organic EL element layer forming step, and a sealing film forming step.

### TFT Layer Forming Step

First, after forming the first metal film, by forming a copper film (having a thickness of approximately 300 nm) or the like by, for example, sputtering on the glass substrate 10, the first metal film is patterned to form the first capacitance electrode 11c, the third terminal layer 11t, and the like.

Subsequently, a silicon nitride film (having a thickness of approximately 150 nm) and the like is formed by, for example, a plasma chemical vapor deposition (CVD) method on the substrate surface on which the first capacitance electrode 11c or the like is formed, thereby forming the base insulating film 12 as the first inorganic insulating film.

Thereafter, after forming the second metal film by forming a copper film (having a thickness of approximately 300 nm) or the like by, for example, sputtering on the substrate surface on which the base insulating film 12 is formed, the second metal film is patterned to form the first gate electrode 13a, the second capacitance electrode 13b, and the like.

Further, on the substrate surface on which the first gate electrode 13a and the like are formed, a silicon nitride film (having a thickness of approximately 100 nm) and a silicon oxide film (having a thickness of approximately 200 nm) are sequentially formed by, for example, plasma CVD, thereby forming the first gate insulating film 14 as the second inorganic insulating film.

Subsequently, after forming a semiconductor film (having a thickness of approximately 50 nm) such as InGaZnO₄ by, for example, sputtering on the substrate surface on which the first gate insulating film 14 is formed, the semiconductor film is patterned to form the semiconductor layer 15a and the like.

Thereafter, after forming a silicon oxide film (having a thickness of about 200 nm) by, for example, plasma CVD on the substrate surface on which the semiconductor layer 15a and the like are formed, and subsequently forming the third metal film by forming a copper film (having a thickness of approximately 300 nm) by, for example, sputtering. the layered films are patterned to form the second gate insulating film 16a as the third inorganic insulating film, and to form the second gate electrode 19a, the gate line 19g, the light emission control line 19e, and the like.

Furthermore, after sequentially forming a silicon oxide film (having a thickness of approximately 300 nm) and a silicon nitride film (having a thickness of approximately 200 nm) by, for example, plasma CVD on the substrate surface on which the second gate insulating film 16a and the like are formed, the layered films, the first gate insulating film 14, and the base insulating film 12 are patterned to form a contact hole, thereby forming the interlayer insulating film 20 as the fourth inorganic insulating film. A part of the semiconductor layer 15a is made conductive by heat treatment when forming the interlayer insulating film 20, so that the source region 15ac, the drain region 15ab, and the channel region 15ac are formed in the semiconductor layer 15a.

Subsequently, after forming the fourth metal film by forming a copper film (having a thickness of approximately 300 nm) by for example, sputtering on the substrate surface on which the interlayer insulating film 20 is formed, the fourth metal film is patterned, to form the source line 23f, the power source line 23g, the source electrode 23a, the drain electrode 23b, the wiring line layer 23c, the first wiring line layer 23d, the wiring line layer 23e, the second terminal layer 23t, and the like.

Thereafter, after forming the fifth inorganic insulating film by sequentially forming a silicon oxide film (having a thickness of approximately 150 nm) and a silicon nitride film (having a thickness of approximately 100 nm) by, for example, a plasma CVD on the substrate surface on which the source line 23f and the like are formed, and subsequently applying a polyimide-based photosensitive resin film (having a thickness of approximately 2 μm) by, for example, a spin coating method or a slit coating method, the photosensitive resin film is prebaked, exposed, developed, and postbaked to form the first flattening film 25a, and the fifth inorganic insulating film exposed from the first flattening film 25a is etched to form the protective insulating film 24a.

Further, after forming a layered conductive film of the ITO film and the copper film (fifth metal film) by sequentially forming an ITO film (having a thickness of approximately 50 nm) and a copper film (having a thickness of approximately 300 nm) by, for example, sputtering on the substrate surface on which the protective insulating film 24a is formed, the layered conductive film is patterned to form the relay electrode 26a, the second wiring line layer 26 b, the first terminal layer 26t, and the like.

Subsequently, after forming the sixth metal film by forming a titanium film (having a thickness of from approximately 30 nm to approximately 70 nm) or the like by, for example, sputtering on the substrate surface on which the relay electrode 26a and the like are formed, the sixth metal film is patterned to form the first metal layer 27a, the second metal layer 27b, the third metal layer 27t, and the like.

Finally, after applying a polyimide-based photosensitive resin film (having a thickness of approximately 2 μm) to the substrate surface on which the first metal layer 27a and the like are formed by, for example, a spin coating method or a slit coating method, pre-baking, exposing, developing, and post-baking are performed on the photosensitive resin film to form the second flattening film 28a.

### Organic EL Element Layer Forming Step

First, after sequentially forming an ITO film (having a thickness of approximately 50 nm) and a silver film (having a thickness of approximately 100 nm) by, for example, sputtering, on the second flattening film 28a formed in the TFT layer forming step, the layered film is patterned by, for example, wet etching using a mixed solution of phosphoric acid, nitric acid, and acetic acid to form the reflective electrode R and the like including the transparent conductive layer 31a and the metal layer 32a.

Subsequently, after forming an inorganic insulating film such as a silicon nitride film (having a thickness of approximately 100 nm) by, for example, plasma CVD on the substrate surface on which the reflective electrode R and the like are formed, the inorganic insulating film is patterned to form the first edge cover 33a.

Thereafter, after forming an ITO film (having a thickness of approximately 100 nm) by, for example, sputtering on the substrate surface on which the first edge cover 33a and the like are formed, the ITO film is patterned by, for example, wet etching using oxalic acid to form the transparent electrode 34a and the fourth terminal layer 34b.

Further, after forming a silicon nitride film (having a thickness of approximately 250 nm) and the like by, for example, plasma CVD on the substrate surface on which the transparent electrode 34a and the like are formed, the silicon nitride film is patterned to form the second edge cover 35a.

Subsequently, the hole injection layer 1, the hole transport layer 2, the light-emitting layer 3, the electron transport layer 4, and the electron injection layer 5 each having a thickness from approximately several 10 nm to approximately 50 nm are sequentially formed by, for example, a vacuum vapor deposition technique on the substrate surface on which the second edge cover 35a is formed, thereby forming the organic EL layer 36.

Finally, on the substrate surface on which the organic EL layer 36 is formed, a transparent conductive film such as an ITO film (having a thickness of approximately 100 nm) is formed by sputtering by using a mask for film formation to form the second electrode 37.

As described above, the organic EL element layer 40 can be formed.

### Sealing Film Forming Step

First, an inorganic insulating film such as a silicon nitride film, a silicon oxide film, or a silicon oxynitride film is formed by plasma CVD on a substrate surface formed with the organic EL element layer 40 formed in the organic EL element layer forming step described above by using a film formation mask to form the first inorganic sealing film 41.

Next, on the substrate surface on which the first inorganic sealing film 41 is formed, a film made of an organic resin material such as acrylic resin is formed by, for example, using an ink-jet method to form the organic sealing film 42.

Finally, an inorganic insulating film such as a silicon nitride film, a silicon oxide film, or a silicon oxynitride film is formed by plasma CVD on the substrate surface formed with the organic sealing film 42 by using a film formation mask to form the second inorganic sealing film 43, thereby forming the sealing film 45.

The organic EL display device 50a can be manufactured as described above.

As described above, according to the organic EL display device 50a of the present embodiment, in each subpixel P, the relay electrode 26a disposed as the low-resistance conductive layer including the copper film in the TFT layer 30 and electrically connected to the first electrode E including the silver film of the organic EL element layer 40 is covered with the first metal layer 27a formed of the titanium film or the titanium alloy film. Thus, even when the layered film of the ITO film and the silver film is patterned by wet etching using the mixed solution of phosphoric acid, nitric acid, and acetic acid in order to form the reflective electrode R of the first electrode E, the etching solution is blocked by the first metal layer 27a, and is less likely to penetrate into the relay electrode 26a. This makes it possible to protect the copper film of the relay electrode 26a from the etching solution, and thus it is possible to suppress corrosion of the relay electrode 26a using the copper film of the TFT layer 30 electrically connected to the first electrode E using the silver film.

In addition, according to the organic EL display device 50a of the present embodiment, since the inorganic insulating film is not disposed between the relay electrode 26a and the reflective electrode R, it is easy to control an inclination of an inner side surface of the contact hole formed in the second flattening film 28a, and thus it is possible to easily secure the electrical connection between the relay electrode 26a and the reflective electrode R.

### Second Embodiment

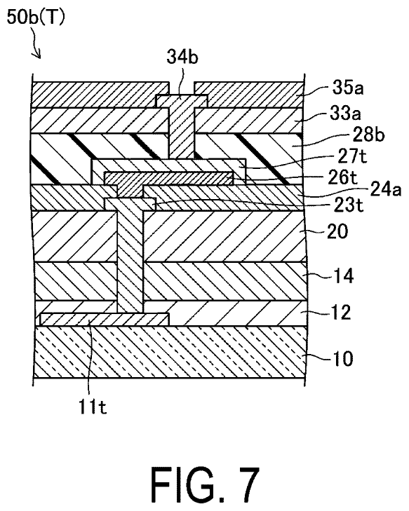

FIG. 7 illustrates a second embodiment of the display device according to the disclosure. Here, FIG. 7 is a cross-sectional view of the terminal portion T of an organic EL display device 50b of the present embodiment. Note that, in the following embodiments, portions identical to those in FIG. 1 to FIG. 6 are denoted by the same reference signs, and their detailed descriptions are omitted.

In the first embodiment, the organic EL display device 50a in which the second flattening film 28a in the display region D is also provided in the terminal portion T as it is is exemplified, but in the present embodiment, an organic EL display device 50b in which a second flattening film 28b having a smaller film thickness than the second flattening film 28a in the display region D is provided in the terminal portion T will be exemplified.

Similarly to the organic EL display device 50a of the first embodiment, the organic EL display device 50b, includes, for example, the display region D provided in a rectangular shape for displaying images and a frame region F provided in a frame-like shape around the display region D and including the terminal portion T. Additionally, similarly to the organic EL display device 50a of the first embodiment described above, the organic EL display device 50b includes the glass substrate 10 provided as the base substrate, the TFT layer 30 provided on the glass substrate 10, the organic EL element layer 40 provided as the light-emitting element layer on the TFT layer 30, and the sealing film 45 provided on the organic EL element layer 40. Here, the configuration of the display region D of the organic EL display device 50b is substantially the same as that of the organic EL display device 50a of the first embodiment, and thus, the configuration of the terminal portion T of the organic EL display device 50b will be mainly described in the present embodiment.

Similarly to the organic EL display device 50a of the first embodiment described above, the organic EL display device 50b includes the plurality of first terminal layers 26t (see FIG. 7) provided along a direction, in which the terminal portion T extends, in the terminal portion T in the frame region F and formed of the fifth metal film. Here, as illustrated in FIG. 7, instead of the second flattening film 28a (see FIG. 4) of the first embodiment, the second flattening film 28b is provided in the terminal portion T. The film thickness of the second flattening film 28b is, for example, about 1 μm, which is smaller than the film thickness (approximately 2 μm) of the second flattening film 28a provided in the display region D. The other configurations of the terminal portion T of the organic EL display device 50b is substantially the same as that of the configurations of the terminal portion of the organic EL display device 50a of the first embodiment described above.

Similarly to the organic EL display device 50a of the first embodiment described above, in the organic EL display device 50b having the configuration described above, image display is performed by causing the light-emitting layer 3 of the organic EL layer 36 of the organic EL element 39 to emit light as appropriate via the first TFT 9a, the second TFT 9b, and the third TFT 9c in each subpixel P.

The organic EL display device 50b of the present embodiment can be manufactured by performing exposure of the photosensitive resin film when forming the second flattening film 28a with, for example, a half tone mask in the TFT layer forming step of the manufacturing method for the organic EL display device 50a of the first embodiment.

As described above, according to the organic EL display device 50b of the present embodiment, in each subpixel P, the relay electrode 26a disposed as the low-resistance conductive layer including the copper film in the TFT layer 30 and electrically connected to the first electrode E including the silver film of the organic EL element layer 40 is covered with the first metal layer 27a formed of the titanium film or the titanium alloy film. Thus, even when the layered film of the ITO film and the silver film is patterned by wet etching using the mixed solution of phosphoric acid, nitric acid, and acetic acid in order to form the reflective electrode R of the first electrode E, the etching solution is blocked by the first metal layer 27a, and is less likely to penetrate into the relay electrode 26a. This makes it possible to protect the copper film of the relay electrode 26a from the etching solution, and thus it is possible to suppress corrosion of the relay electrode 26a using the copper film of the TFT layer 30 electrically connected to the first electrode E using the silver film.

In addition, according to the organic EL display device 50b of the present embodiment, since the inorganic insulating film is not disposed between the relay electrode 26a and the reflective electrode R, it is easy to control an inclination of an inner side surface of the contact hole formed in the second flattening film 28a, and thus it is possible to easily secure the electrical connection between the relay electrode 26a and the reflective electrode R.

In addition, according to the organic EL display device 50b of the present embodiment, since the second flattening film 28b provided in the terminal portion T is thinner than the second flattening film 28a provided in the display region D, the depth of the contact hole formed in the second flattening film 28b and the first edge cover 33a is shallow, and the electrical connection between the first terminal layer 26t and the fourth terminal layer 34b can be easily secured.

### Third Embodiment

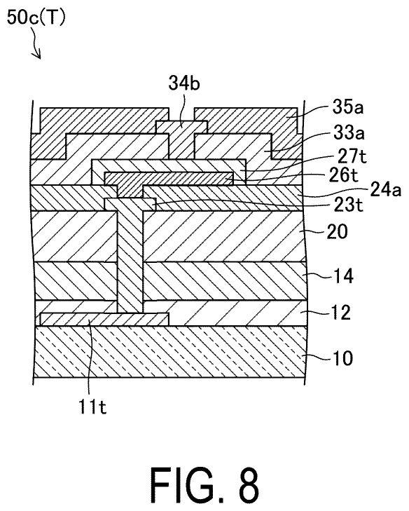

FIG. 8 illustrates a third embodiment of the display device according to the disclosure. Here, FIG. 8 is a cross-sectional view of the terminal portion T of an organic EL display device 50c of the present embodiment.

In the first embodiment and the second embodiment described above, the organic EL display devices 50a and 50b in which the second flattening films 28a and 28b are formed in the terminal portion T are exemplified. However, in the present embodiment, the organic EL display device 50c in which the flattening film is not provided in the terminal portion T is exemplified.

Similarly to the organic EL display device 50a of the first embodiment, the organic EL display device 50c, includes, for example, the display region D provided in a rectangular shape for displaying images and a frame region F provided in a frame-like shape around the display region D and including the terminal portion T. Additionally, similarly to the organic EL display device 50a of the first embodiment described above, the organic EL display device 50c includes the glass substrate 10 provided as the base substrate, the TFT layer 30 provided on the glass substrate 10, the organic EL element layer 40 provided as the light-emitting element layer on the TFT layer 30, and the sealing film 45 provided on the organic EL element layer 40. Here, the configuration of the display region D of the organic EL display device 50c is substantially the same as that of the organic EL display device 50a of the first embodiment, and thus, the configuration of the terminal portion T of the organic EL display device 50c will be mainly described in the present embodiment.

Similarly to the organic EL display device 50a of the first embodiment described above, the organic EL display device 50c includes the plurality of first terminal layers 26t (see FIG. 8) provided along a direction, in which the terminal portion T extends, in the terminal portion T in the frame region F and formed of the fifth metal film. Here, as illustrated in FIG. 8, the first flattening film 25a and the second flattening film 28a in the display region D are not provided in the terminal portion T. The other configurations of the terminal portion T of the organic EL display device 50c is substantially the same as that of the configurations of the terminal portion of the organic EL display device 50a of the first embodiment described above.

Similarly to the organic EL display device 50a of the first embodiment described above, in the organic EL display device 50c having the configuration described above, display is imaged by causing the light-emitting layer 3 of the organic EL layer 36 of the organic EL element 39 to emit light as appropriate via the first TFT 9a, the second TFT 9b, and the third TFT 9c in each subpixel P.

The organic EL display device 50c of the present embodiment can be manufactured by changing the pattern shape of the second flattening film 28a in the TFT layer forming step in the manufacturing method for the organic EL display device 50a of the first embodiment.

As described above, according to the organic EL display device 50c of the present embodiment, in each subpixel P, the relay electrode 26a disposed as the low-resistance conductive layer including the copper film in the TFT layer 30 and electrically connected to the first electrode E including the silver film of the organic EL element layer 40 is covered with the first metal layer 27a formed of the titanium film or the titanium alloy film. Thus, even when the layered film of the ITO film and the silver film is patterned by wet etching using the mixed solution of phosphoric acid, nitric acid, and acetic acid in order to form the reflective electrode R of the first electrode E, the etching solution is blocked by the first metal layer 27a, and is less likely to penetrate into the relay electrode 26a. This makes it possible to protect the copper film of the relay electrode 26a from the etching solution, and thus it is possible to suppress corrosion of the relay electrode 26a using the copper film of the TFT layer 30 electrically connected to the first electrode E using the silver film.

In addition, according to the organic EL display device 50c of the present embodiment, since the inorganic insulating film is not disposed between the relay electrode 26a and the reflective electrode R, it is easy to control an inclination of an inner side surface of the contact hole formed in the second flattening film 28a, and thus it is possible to easily secure the electrical connection between the relay electrode 26a and the reflective electrode R.

In addition, according to the organic EL display device 50c of the present embodiment, since the second flattening film 28a of the display region D is not provided in the terminal portion T, the depth of the contact hole formed in the first edge cover 33a is further shallow, and the electrical connection between the first terminal layer 26t and the fourth terminal layer 34b can be further easily secured.

### Other Embodiments

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

Although the organic EL display device in which the electrode of the TFT connected to the first electrode serves as the drain electrode has been exemplified in each of the embodiments described above, the disclosure is also applicable to an organic EL display device in which the electrode of the TFT connected to the first electrode is referred to as the source electrode.

In each of the embodiments described above, the organic EL display device has been exemplified as the display device. The disclosure can also be applied to a display device including a plurality of light-emitting elements to be driven by a current, for example, to a display device including quantum dot light emitting diodes (QLEDs), each of which is a light-emitting element using a quantum dot-containing layer.

### INDUSTRIAL APPLICABILITY

As described above, the disclosure is useful for self-luminous display devices.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a base substrate;
a thin film transistor layer provided on the base substrate and including a low-resistance conductive layer including a copper film, the low-resistance conductive layer being disposed corresponding to each subpixel of a plurality of subpixels constituting a display region; and
a light-emitting element layer provided on the thin film transistor layer and including a plurality of first electrodes, a plurality of light-emitting function layers, and a common second electrode sequentially layered corresponding to the plurality of subpixels,
wherein each of the first electrodes includes a silver film and is electrically connected to the low-resistance conductive layer, and
the low-resistance conductive layer is covered with a first metal layer having etching resistance to an etching solution for the silver film.

2. The display device according to claim 1,
wherein the first metal layer is formed of a titanium film or a titanium alloy film.

3. The display device according to claim 1,
wherein the etching solution includes phosphoric acid, nitric acid, and acetic acid.

4. The display device according to claim 1,
wherein in the thin film transistor layer, a first metal film, a first inorganic insulating film, a second metal film, a second inorganic insulating film, a semiconductor film, a third inorganic insulating film, a third metal film, a fourth inorganic insulating film, a fourth metal film, a fifth inorganic insulating film, a first organic insulating film, a fifth metal film including the copper film, a sixth metal film, and a second organic insulating film are sequentially layered on the base substrate,
the low-resistance conductive layer is formed of the fifth metal film, and
the first metal layer is formed of the sixth metal film.

5. The display device according to claim 4,
wherein a thin film transistor is disposed in the thin film transistor layer, the thin film transistor including
a semiconductor layer including a source region and a drain region defined to be separated from each other and a channel region defined between the source region and the drain region and formed of the semiconductor film,
a first gate electrode provided on the base substrate side of the semiconductor layer with the second inorganic insulating film interposed therebetween and formed of the second metal film,
a second gate electrode provided on the channel region with the third inorganic insulating film interposed therebetween and formed of the third metal film, and
a source electrode and a drain electrode electrically connected to the source region and the drain region, respectively, and formed of the fourth metal film, and
the low-resistance conductive layer is electrically connected to the drain electrode.

6. The display device according to claim 4,
wherein a capacitor is disposed in the thin film transistor layer, the capacitor including
a first capacitance electrode formed of the first metal film,
a second capacitance electrode formed of the second metal film, and
the first inorganic insulating film provided between the first capacitance electrode and the second capacitance electrode,
the second capacitance electrode is electrically connected to a first wiring line layer formed of the fourth metal film,
the first wiring line layer is electrically connected to a second wiring line layer formed of the fifth metal film, and
the second wiring line layer is covered with a second metal layer formed of the sixth metal film.

7. The display device according to claim 4,
wherein each of the first electrodes includes a reflective electrode including the silver film and a transparent electrode provided on the reflective electrode,
a frame region is provided around the display region,
a terminal portion is provided at an end portion of the frame region,
the terminal portion is provided with a first terminal layer formed of the fifth metal film,
the first terminal layer is electrically connected to a second terminal layer formed of the fourth metal film,
the second terminal layer is electrically connected to a third terminal layer formed of the first metal film,
the first terminal layer is covered with a third metal layer formed of the sixth metal film, and
the third metal layer is electrically connected to a fourth terminal layer formed of the same material and in the same layer as the transparent electrode.

8. The display device according to claims 7,
wherein in the terminal portion, the first organic insulating film is not provided and the second organic insulating film is provided.

9. The display device according to claim 8,
wherein the second organic insulating film provided in the terminal portion is thinner than the second organic insulating film provided in the display region.

10. The display device according to claim 7,
wherein in the terminal portion, the first organic insulating film and the second organic insulating film are not provided.

11. The display device according to claim 1, further comprising:
a sealing film provided on the light-emitting element layer.

12. The display device according to claim 1,
wherein at least one of the plurality of light-emitting function layers is an organic electroluminescence layer.
